(19) United States
(12) Patent Application Publication
(10) Pub. No.: US 2009/0324825 A1
(43) Pub. Date: Dec. 31, 2009

(54) Method for Depositing an Aluminum Nitride Coating onto Solid Substrates

(76) Inventors: Carl R. EVENSON, Lafayette, CO (US); Erick J. SCHUTTE, Thornton, CO (US); Joel S. THOMPSON, Broomfield, CO (US)

Correspondence Address: GREENLEE WINNER AND SULLIVAN P C, 4875 PEARL EAST CIRCLE, SUITE 200, BOULDER, CO, 80301, US

(21) Appl. No.: 12/474,833

(22) Filed: May 29, 2009

Related U.S. Application Data
(60) Provisional application No. 61/057,288, filed on May 30, 2008.

(51) Int. Cl. C23C 16/44; C23C 16/455; C23C 16/34; C23C 16/40

(52) U.S. Cl. 427/255.22; 427/248.1; 427/255.11; 427/255.21; 427/255.395

(57) ABSTRACT

Embodiments related to chemical vapor deposition of aluminum nitride onto surfaces are provided. In particular, methods are provided for coating AlN onto solid surfaces by heating and vaporizing an aluminum nitride precursor and exposing solid surfaces to the heated and vaporized aluminum nitride precursor. In an embodiment, the aluminum nitride precursor is AlCl₃(NH₃)ₓ, wherein x=1-6. In an embodiment, the surface is a metallic substrate, such as a silicon, aluminum nitride, steel, aluminum, molybdenum and manganese. In an embodiment, the surface is steel that is nitrided to form an iron nitride layer on which AlN is deposited.

### CROSS-REFERENCE TO RELATED APPLICATIONS

This application claims the benefit of U.S. Provisional Application No. 61/057,288, filed May 30, 2008 which is incorporated by reference herein to the extent not inconsistent herewith.

### STATEMENT REGARDING FEDERALLY SPONSORED RESEARCH OR DEVELOPMENT

This invention was made with government support under DE-FG02-04ER83939 awarded by the Department of Energy. The government has certain rights in the invention.

### BACKGROUND OF THE INVENTION

Provided are methods and systems for depositing aluminum nitride (AlN) onto a solid surface. Aluminum nitride coatings function as thermal, electrical, or corrosion resistant barriers. Chemical vapor deposition (CVD) of aluminum nitride and formation of an iron nitride surface on steel are known and practiced technologies. Disclosed herein are various processes and systems for high-rate AlN deposition on various surfaces not achievable with conventional deposition as practiced in the art. For example, Alexandrov et al. (Kinetics of LPCVD of aluminum nitride films based on pyrolysis of aluminum chloride complex. J. Phys. IV France 11 (2001):Pr3-155-Pr3-161) relates to AlN layers by CVD of AlCl₃(NH₃) at low vaporization temperature (400-420 K) and pressures (30-600 Pa, corresponding to 0.225 torr-4.5 torr). In that study, it was acknowledged that AlN deposition by CVD at pressures less than 200 Pa (1.5 torr) is not practical due to “a significant decrease in the growth rate.” Provided herein are processes and systems that are unexpectedly capable of providing high quality dense AlN deposition at a high-rate and a low pressure, such as less than about 2 torr. Provided are processes and systems for dense, high coverage deposition of AlN at a high rate. In addition, provided are materials having a corrosion resistant layer of AlN deposited and adhered onto steel having an iron nitride surface and processes and systems for deposition of such materials.

### SUMMARY OF THE INVENTION

Provided are chemical vapor deposition processes for depositing dense aluminum nitride onto a solid surface. The solid is heated under a partial vacuum and an aluminum nitride precursor is vaporized and carried past the solid surface where thermal decomposition occurs to deposit AlN on the solid surface. In an embodiment, the precursor is an aluminum chloride ammonia complex with the formula AlCl₃(NH₃)ₓ where x=1-6. The solid substrate can be metallic or ceramic. Examples of substrates include, but are not limited to, aluminum nitride, steel, molybdenum, or silicon. Any of the deposition methods are optionally carried out at user-selected processing variables such as temperature, pressure, flow-rates, deposition rate, duration of deposition, etc., as desired. As disclosed herein, any one or more of the processing variables can be selected to affect deposition characteristics, thereby influencing a functional attribute of the coated system, such as deposition density and composition, substrate surface composition, and adherence of the coating with an underlying substrate. In an embodiment, the deposition method occurs at a temperature selected from between about 250 to about 1000° C. and a pressure selected from between about 50 to about 2000 mTorr, or between 50 mTorr to less than 1500 mTorr (200 Pa). In any of the processes provided herein, the substrate to be coated is optionally heated as desired, for example, heated under a desired partial vacuum.

For deposition onto steel, the process optionally further includes pre-treating the steel surface prior to deposition of AlN. Optionally, the pre-treating is ended before or, alternatively, substantially simultaneously to the time AlN deposition is initiated. Alternatively, the pre-treating substantially continues during at least part of the subsequent deposition of AlN. The steel is heated to between 450 and 650° C. under a mixed gas stream of ammonia and hydrogen to form an iron nitride (e.g., FeₓN where x is a whole number and 1≦x≦5). AlN is then deposited onto the iron nitride as described above. Iron nitride acts as an interface between the AlN and steel to improve bonding. During the deposition process the iron nitride phase may change, such as wherein x may increase or decrease during deposition.

For corrosion resistant coatings, the surface of the AlN is optionally further reacted to produce an aluminum oxide (Al₂O₃) layer on at least a portion of the surface of the AlN, or over the entire surface of the AlN, such as by reaction with air and/or O₂.

Without wishing to be bound by any particular theory, there can be discussion herein of beliefs or understandings of underlying principles relating to the invention. It is recognized that regardless of the ultimate correctness of any mechanistic explanation or hypothesis, an embodiment of the invention can nonetheless be operative and useful.

### BRIEF DESCRIPTION OF THE DRAWINGS

FIG. 1. X-ray diffraction pattern for a 1018 carbon steel surface nitrided at 550° C. in a 100% NH₃ atmosphere. All diffraction peaks correspond to FeₓN (x=2-3).

FIG. 2. X-ray diffraction pattern for a 1018 carbon steel surface nitrided at 550° C. in an 80% NH₃, 20% H₂ atmosphere. An asterisk indicates diffraction peaks corresponding to Fe₄N. A plus sign indicates peaks corresponding to Fe.

FIG. 3. ×1000 SEM image of 1018 carbon steel before nitriding.

FIG. 4. SEM images of 1018 carbon steel with a Fe₃N surface. Left: ×1000. Right: ×5000.

FIG. 5. SEM images of 1018 carbon steel with a Fe₄N/Fe surface. Left: ×1000. Right: ×5000.

FIG. 6. Digital image of AlN coating deposited onto 1018 carbon steel with a Fe₃N surface at 650° C.

FIG. 7. Digital image of AlN coating deposited onto 1018 carbon steel with a Fe₄N/Fe surface at 650° C.

FIG. 8. X-ray diffraction pattern for the sample in which AlN is deposited onto a Fe₃N carbon steel surface at 650° C. Unlabelled diffraction peaks correspond to AlN, an asterisk indicates Fe₄N, and a plus sign indicates Fe.

FIG. 9. X-ray diffraction pattern for the sample in which AlN is deposited onto a Fe₄N/Fe carbon steel surface at 650° C. Unlabelled diffraction peaks correspond to AlN, an arrow indicates Fe₃N, an asterisk indicates Fe₄N, and a plus sign indicates Fe.

FIG. 10. SEM images of AlN deposited onto 1018 carbon steel with a Fe₃N surface at 650° C. Left: ×1000 image. Right: ×2500 image.

FIG. 11. SEM images of AlN deposited onto 1018 carbon steel with a Fe₄N/Fe surface at 650° C. Left: ×1000 image. Right: ×2500 image.

FIG. 12. Digital image of the AlN coating deposited onto a 1018 carbon steel coupon with a Fe₃N surface at 700° C.

FIG. 13. Digital image of the AlN coating deposited onto a 1018 carbon steel coupon with a Fe₄N/Fe surface at 700° C.

FIG. 14. X-ray diffraction pattern for the sample in which AlN is deposited onto a Fe₃N carbon steel surface at 700° C. Unlabelled diffraction peaks correspond to AlN, an asterisk indicates Fe₄N, and a plus sign indicates Fe.

FIG. 15. X-ray diffraction pattern for the sample in which AlN is deposited onto a Fe₄N/Fe carbon steel surface at 700° C. Unlabelled diffraction peaks correspond to AlN, an asterisk indicates Fe₄N, and a plus sign indicates Fe.

FIG. 16. SEM images of AlN deposited onto 1018 carbon steel with a Fe₃N surface at 700° C. Left: ×1000 image. Right: ×2500 image.

FIG. 17. SEM images of AlN deposited onto 1018 carbon steel with a Fe₄N/Fe surface at 700° C. Left: ×1000 image. Right: ×2500 image.

FIG. 18. Cross section ×2500 SEM image of AlN deposited onto 1018 carbon steel with a Fe₃N surface at 700° C. The light gray on the left side is the 1018 carbon steel, the darker gray in the middle is dense AlN, and the black on the right is mounting epoxy.

FIG. 19. Cross section ×2500 SEM image of AlN deposited onto 1018 carbon steel with a Fe₄N/Fe surface at 700° C. The black area on the left is mounting epoxy, the dark gray in the middle is the dense AlN coating, and the light gray on the right side is the 1018 carbon steel.

FIG. 20. X-ray patterns of AlN on 1018 carbon steel before and after partially oxidizing the surface of AlN to Al₂O₃. Top: AlN adhered to 1018 carbon steel. Bottom: AlN on 1018 carbon steel with partially oxidized surface.

FIG. 21. Top: Interior of 1018 steel pipe following AlN deposition. Center of pipe contains an AlN coating. The ends of the pipe are outside the hot zone of the furnace and do not have an AlN coating. Middle: 1018 steel pipe after 6 months exposed to air. Bottom: 1018 steel pipe after 21 months exposed to air.

FIG. 22. Top: 1018 steel pipe following AlN deposition. Note: ends cleaned by mechanical abrasion. Middle: after 336 hours exposed to steam/air at 200° C. Bottom: after 672 hours exposed to steam/air and stagnant water at 200° C.

FIG. 23. Digital image of AlN deposited onto 1018 carbon steel.

FIG. 24. X-ray diffraction pattern for a sample in which AlN is deposited onto a Fe₃N carbon steel surface at 700° C. Unlabelled diffraction peaks correspond to AlN, an asterisk indicates Fe₄N, and a plus sign indicates Fe.

FIG. 25. Optical microscope image of AlN deposited on 1018 carbon steel at 700° C.

FIG. 26. Optical microscope image of AlN deposited on 1018 carbon steel at 700° C. after scoring.

FIG. 27. Optical microscope image of AlN deposited on 1018 carbon steel at 700° C. after tape testing.

FIG. 28. X-ray diffraction pattern for a sample in which AlN is deposited onto a Mo surface. Unlabelled diffraction peaks correspond to AlN and an asterisk indicates peaks corresponding to Mo.

FIG. 29. ×500 SEM image of the surface of AlN deposited on Mo.

FIG. 30. ×2000 SEM image of the cross section of AlN deposited on Mo. Light gray area at the top of the image is Mo, the darker gray in the middle is dense AlN, and the black area at the bottom of the image is mounting epoxy.

FIG. 31. X-ray diffraction pattern for thick AlN coating on Mo. Unlabelled peaks correspond to AlN. An asterisk indicates Mo.

FIG. 32. Left: ×100 and Right: ×400 SEM image of the surface of thick AlN deposited on Mo.

FIG. 33. ×500 SEM image of the cross section of thick AlN deposited onto Mo. The black area at the top of the image is mounting epoxy, the dark gray area in the middle is deposited AlN, and the light gray area at the bottom of the image is Mo.

### DETAILED DESCRIPTION OF THE INVENTION

“High-rate” refers to a deposition rate that is significantly higher compared to conventional AlN deposition rates using chemical vapor deposition. In an aspect, the rate is greater than about 0.05 μm/min, or selected from a range that is greater than or equal to 0.05 μm/min and less than or equal to 10 μm/min.

“Dense” refers to substantial coverage of the underlying substrate by an AlN coating by a process disclosed herein and a lack of AlN defects. In an aspect, the defects, such as cracks, pores and other absence of coverage is less than 1%, less than 0.1% or less than 0.01% the surface area of the substrate that is coated. Alternatively, dense refers to a property of the deposited AlN coating, such as AlN having an average density that is greater than or equal to about 3 g/cm³, or greater than or equal to about 3.2 g/cm³, or about 3.26 g/cm³. In an aspect, the density is selected from a range that is greater than about 3 g/cm³ and less than about 3.3 g/cm³. In an aspect, density refers to bulk density, so that the density of the AlN coating is an average bulk property that includes AlN and also any impurities or defects, such as holes, cracks or pores in the layer.

“Precursor” refers to a composition that is capable of yielding a nitride of aluminum (e.g., AlN) under selected deposition conditions (e.g., temperature, flow-rate, pressure). In an aspect, the aluminum nitride precursor contains aluminum and nitrogen, and heating and vaporizing the precursor results in deposition of aluminum nitride on a surface. In an aspect, the aluminum nitride precursor is an aluminum chloride ammonia complex, such as of the formula:

AlCl₃(NH₃)ₓ

where x is selected from a range that is greater than or equal to 1 and less than or equal to 6.

Alternatively, the AlN may be formed from two or more different materials, wherein the combination of materials is capable of forming AlN or depositing AlN onto a surface including, but not limited to, ammonia and an Al-containing material (e.g., trimethyl- or triethyl-aluminum).

Processes provided herein are useful for generating AlN coatings having a range of thicknesses as desired, ranging from relatively thin, on the order of microns to tens of microns, to thicker layers on the order of hundreds of microns to millimeter scale or greater.

The invention may be further understood by the following non-limiting examples. All references cited herein are hereby incorporated by reference to the extent not inconsistent with the disclosure herewith. Although the description herein contains many specificities, these should not be construed as limiting the scope of the invention but as merely providing illustrations of some of the presently preferred embodiments of the invention. For example, thus the scope of the invention should be determined by the appended claims and their equivalents, rather than by the examples given.

Provided are chemical vapor deposition processes for depositing dense aluminum nitride onto a solid surface. In an embodiment, the deposited aluminum nitride is a ceramic. The solid is heated under a partial vacuum and an aluminum nitride precursor is vaporized and carried past the solid surface where thermal decomposition of the aluminum nitride precursor facilitates deposition of AlN on the solid surface. In one example, the AlN precursor is an aluminum chloride ammonia complex with the formula AlCl₃(NH₃)ₓ where x=1-6. In an aspect x=1. In an aspect, x is selected from the group consisting of 1, 2, 3, 4, 5, 6, and a combination thereof. In an aspect, x≠1. The solid substrate can be metallic or ceramic. Examples of substrates include, but are not limited to, aluminum nitride, steel, molybdenum, or silicon. Any of the deposition methods are optionally carried out at user-selected processing variables such as temperature, pressure, flow-rates, deposition rate, etc., as desired. In an embodiment, the deposition method occurs at a temperature selected from between about 250 to about 1000° C. and a pressure selected from between about 50 to about 2000 mTorr. In any of the processes provided herein, the substrate to be coated is optionally heated as desired, for example, heated under a desired partial vacuum.

For deposition onto steel, the process optionally further includes pre-treating the steel surface prior to deposition of AlN. Alternatively, the pre-treating substantially continues during at least part of the subsequent deposition of AlN. The steel is heated to between 450 and 650° C. under a mixed gas stream, wherein the gas is a nitriding gas composition that is capable of nitriding the surface. In an example, the nitriding gas comprises ammonia and hydrogen to form an iron nitride (FeₓN where x=2-4). AlN is then deposited onto the iron nitride as described above. Iron nitride acts as an interface between the AlN and steel to improve bonding. During the deposition process the iron nitride phase may change, such as FeₓN, wherein x depends on deposition time. In an embodiment, x decreases from 4 to 3.

For corrosion resistant coatings the surface of the AlN can further be reacted to produce an aluminum oxide (Al₂O₃) layer on the surface of the AlN, such as an exposed or “top” surface of AlN.

### EXAMPLE 1

### Chemical Vapor Deposition of AlN onto Steel

AlN is deposited and adhered or bonded to steel by chemical vapor deposition as described below. The CVD AlN precursor for depositing AlN onto steel is AlCl₃(NH₃)ₓ (1≦x≦6). In order to better adhere AlN to steel, a surface preparation step is optionally provided.

Steel Surface Preparation: For depositing an AlN layer onto steel, a nitrided steel surface is used to obtain better adherence of AlN to a surface of the steel. The surface of the steel is nitrided by flowing ammonia or a mixed gas stream of ammonia and hydrogen over the sample at 550° C. Other examples of gas streams that may be used to nitride a steel surface include, but are not limited to mixtures of ammonia, hydrogen, argon, or nitrogen. Other methods of nitriding include rf sputtering, molecular beam epitaxy, and plasma nitriding.

Three different coatings comprising at least one of two different iron nitride compositions can be formed on the steel surface, as desired. By varying the gas composition during the nitriding step coatings were prepared containing Fe₃N, Fe₄N, and a mixture of Fe₃N and Fe₄N. Nitriding conditions and the resulting iron nitride phase are listed in Table 1.

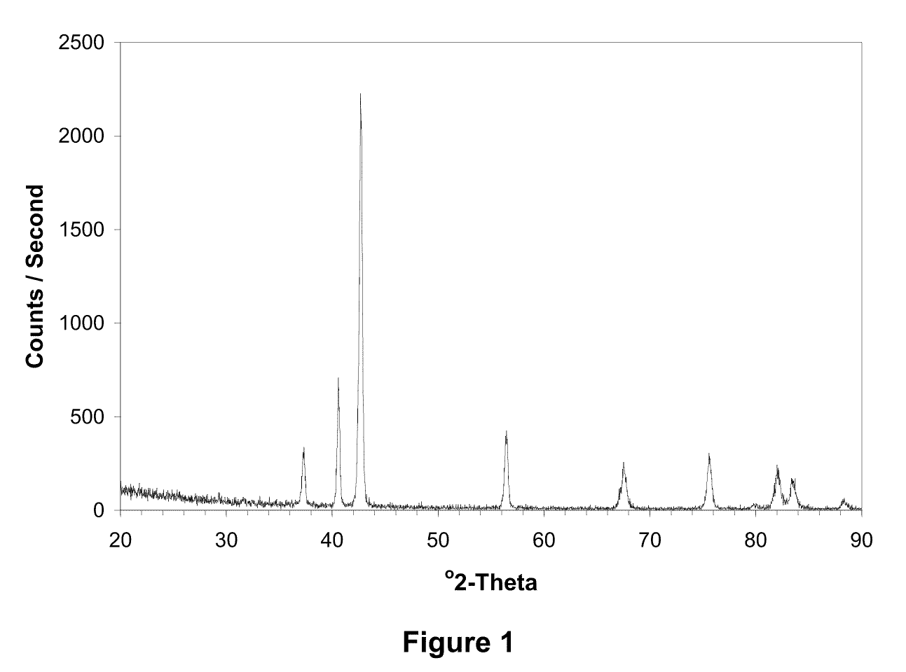

Iron nitride phase formation is determined by X-ray diffraction (XRD). FIG. 1 shows the XRD pattern for a piece of mild steel nitrided at 550° C. under a 100% NH₃ atmosphere.

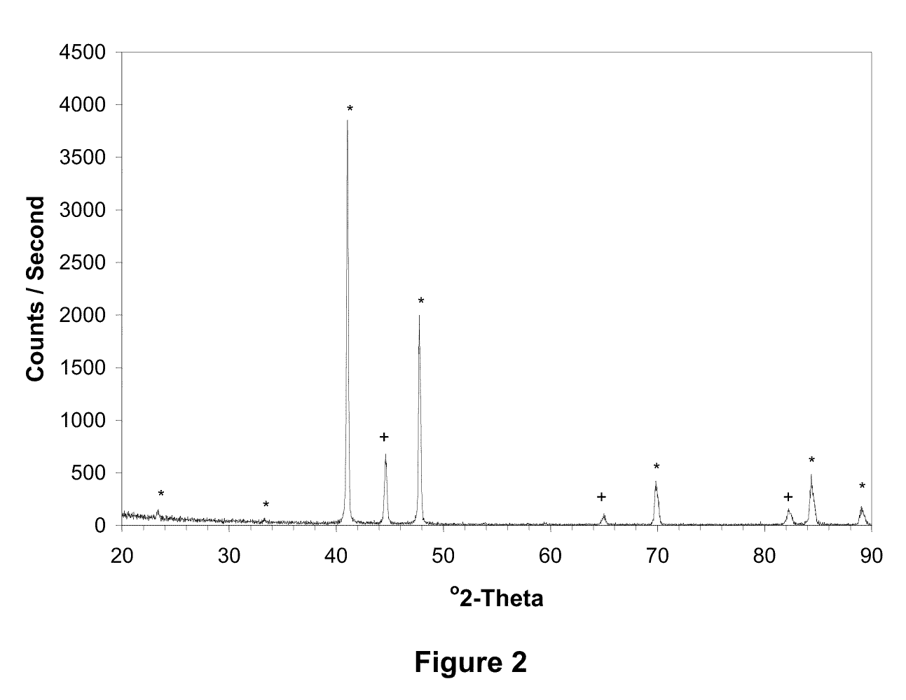

FIG. 1 shows that under these conditions FeₓN (x=2-3), hereafter Fe₃N, is detected on the steel surface. Changing the atmosphere to 80% NH₃ and 20% H₂ results in a surface containing both Fe₄N and Fe as shown in FIG. 2. Accordingly, an aspect of the invention provides manipulation of deposition conditions, particularly atmospheric conditions before and during deposition, to correspondingly vary the surface on which AlN is deposited, thereby controlling adhesive or bonding strength between the AlN coating and underlying substrate.

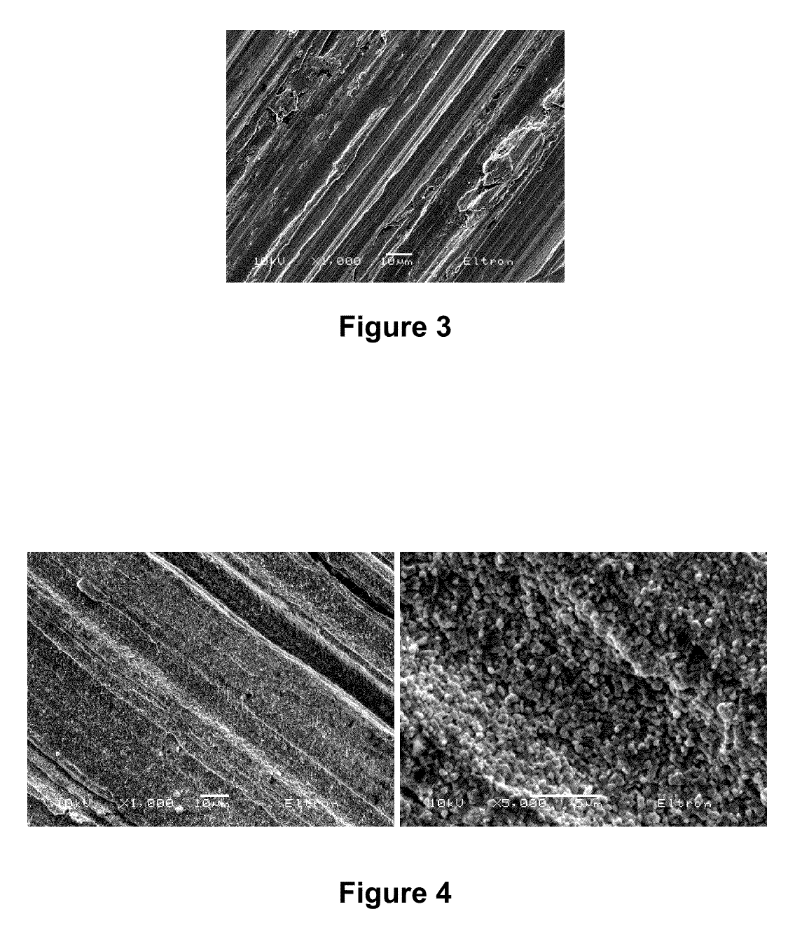

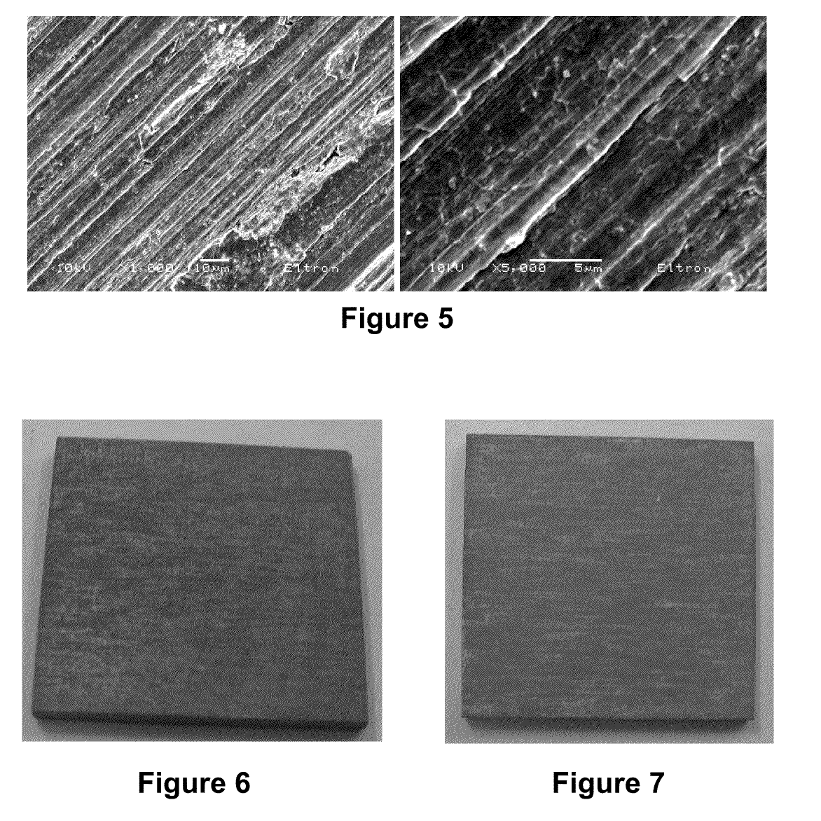

Scanning Electron Microscopy is used to determine the morphology 1018 carbon steel before and after nitriding. FIG. 3 shows the steel surface before nitriding. The surface is rough with a streaked pattern from machining or cutting of the metal. FIG. 4 shows the same metal with a Fe₃N surface. FIG. 5 shows the mixed Fe₄N/Fe surface.

The SEM images in FIGS. 4 and 5 show that the morphology of the Fe₃N and Fe₄N/Fe are very distinct. The Fe₃N surface is very rough and porous while the Fe₄N/Fe surface appears smoother. In both cases the overall streaked pattern found in the uncoated steel in FIG. 3 is still present in the uniformly well-adhered Fe₃N and Fe₄N/Fe surfaces in FIGS. 4 and 5, respectively.

CVD of AlN onto steel: Chemical vapor deposition of AlCl₃(NH₃)ₓ precursor is used to deposit AlN onto Fe₃N and Fe₄N/Fe surfaces. Depositions are performed in a typical cold wall CVD reactor, the details of which are known to those skilled in the art. Vacuum up to 40 mTorr is applied on the right side of the reactor. Carrier gas is supplied on the left side of the reactor and is used to carry vaporized precursor into the CVD chamber containing 1018 carbon steel samples. Using the CVD reactor, AlN is deposited on Fe₃N and Fe₄N/Fe surfaces at two different temperatures: 650 and 700° C.

650° C. AlN Deposition onto a Fe₃N and Fe₄N/Fe Surfaces: AlN is deposited for 30 minutes at 650° C., 4.5 mL/min N₂ carrier gas flow, and 345-885 mTorr of pressure onto two 1018 steel coupons. One coupon has a Fe₃N surface and the second coupon has a Fe₄N/Fe surface. The vacuum started at 345 mTorr and as the precursor is evaporated and carried into the reactor the pressure increases to 885 mTorr. FIGS. 6 and 7 show the surface of the samples following deposition.

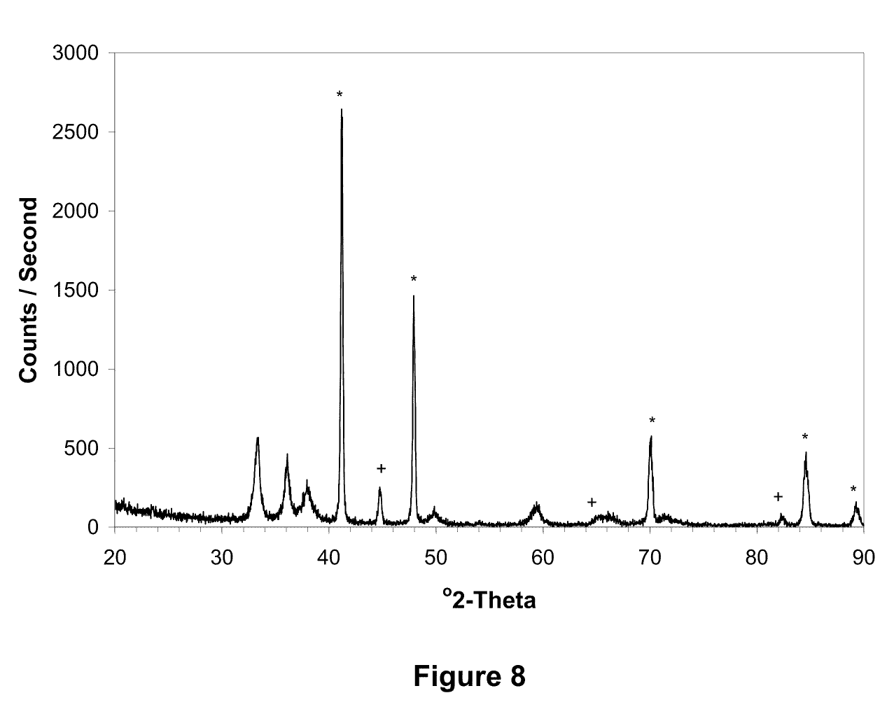

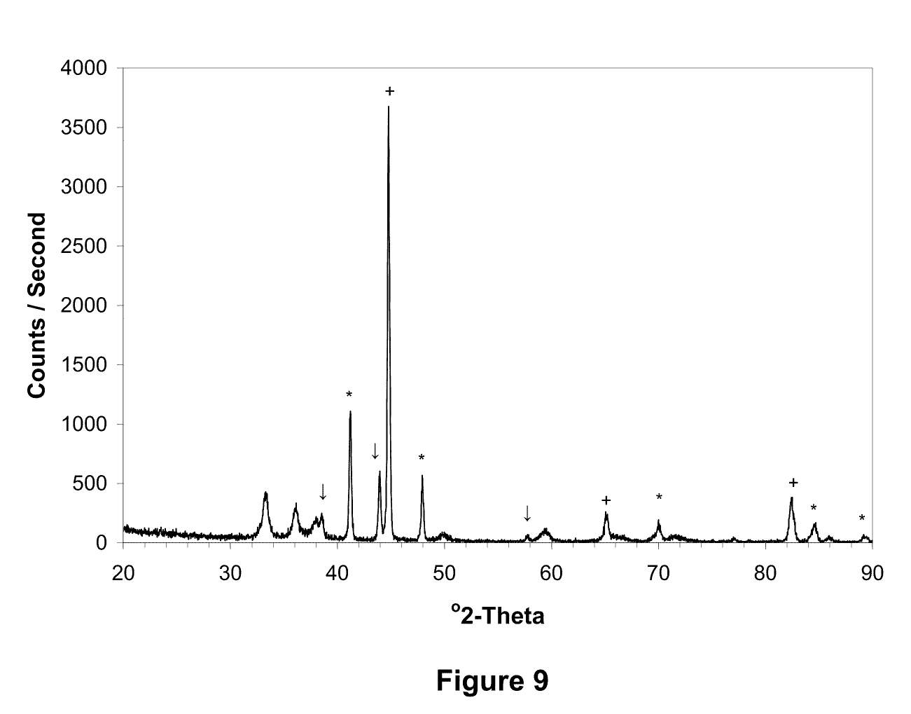

On both samples a uniform coating of AlN is deposited and adhered to the steel surface. X-ray diffraction is used to confirm the composition coatings. FIGS. 8 and 9 show the XRD patterns for these two samples.

FIG. 8 shows that when AlN is deposited onto a Fe₃N surface at 650° C., the iron nitride surface of the steel converts to a Fe₄N/Fe interface with AlN deposited on top. FIG. 9 shows that when AlN is deposited onto a Fe₄N/Fe surface at 650° C., the iron nitride partially converts to Fe₃N and, therefore, Fe₃N, Fe₄N, and Fe are found at the interface between AlN and steel.

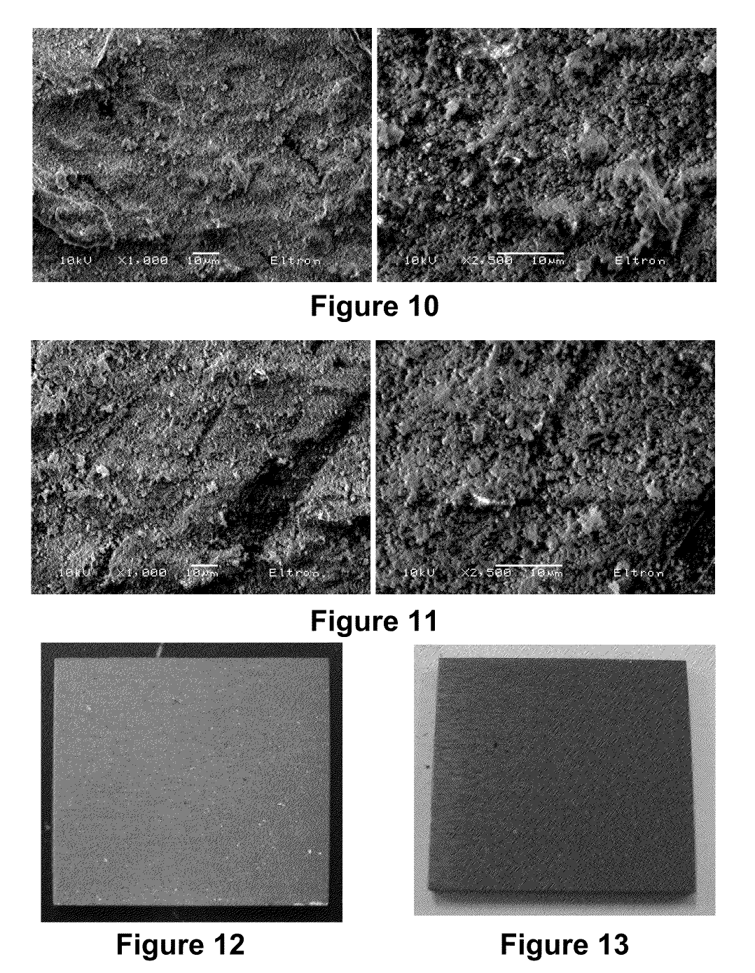

SEM is used to show that the morphology of AlN deposited at 650° C. FIGS. 10 and 11 show the surface of AlN deposited on Fe₃N and Fe₄N/Fe respectively.

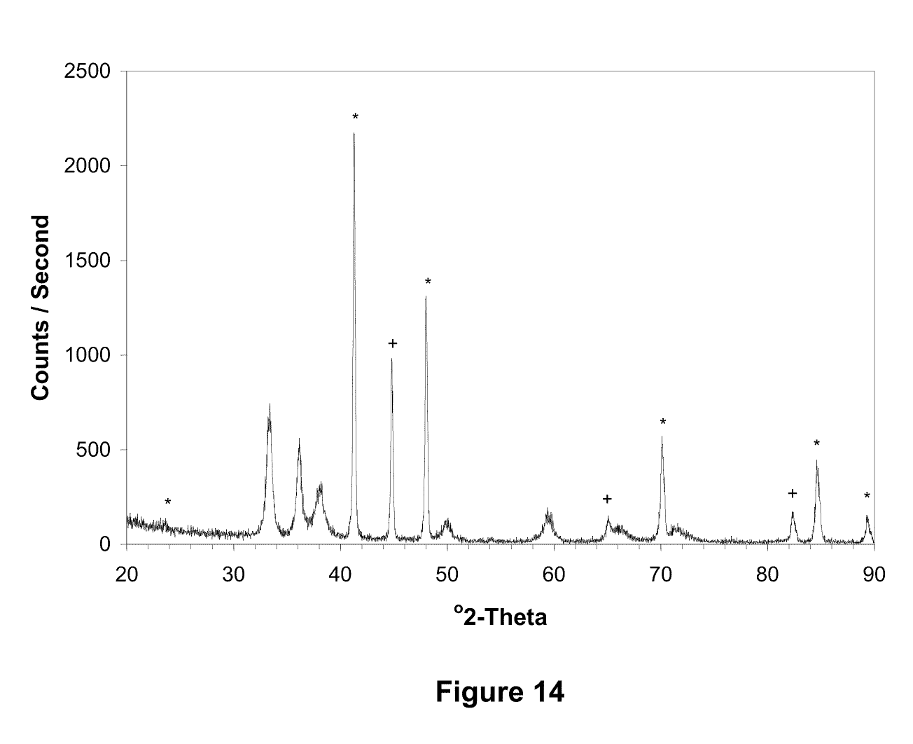

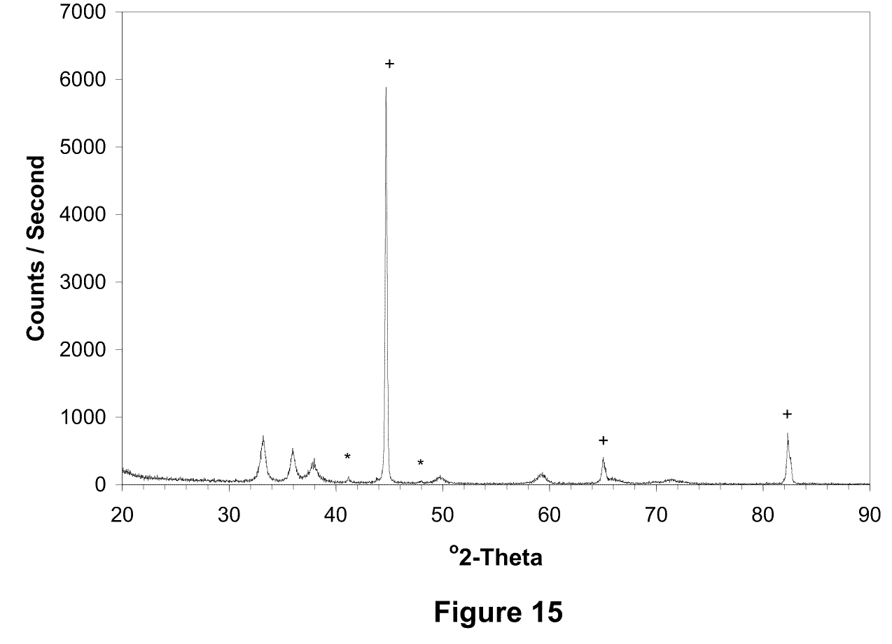

700° C. AlN Deposition onto Fe₃N and Fe₄N/Fe Surfaces: AlN is deposited for 30 minutes at 700° C., 9 mL/min N₂ carrier gas flow, and 502-823 mTorr of pressure onto two 1018 carbon steel coupons. This first coupon has a Fe₃N surface and the second has a Fe₄N/Fe surface. The carrier gas flow rate is increased to keep the deposition pressure range similar to the first experiment. FIGS. 12 and 13 show the surface of the samples following deposition. A uniform coating of AlN is found on each sample. X-ray diffraction, FIGS. 14 and 15 are used to determine the phases present on each sample.

FIGS. 14 and 15 show that deposition of AlN onto both samples results in a Fe₄N/Fe interface between the AlN and steel coupon. Comparing peak heights in FIGS. 14 and 15 shows that qualitatively there is much less Fe₄N/Fe in FIG. 15 than in FIG. 14. Also, when comparing XRD patterns for depositions at 650° C. vs. 700° C., the AlN is qualitatively thicker when deposited at 700° C. for the same length of time.

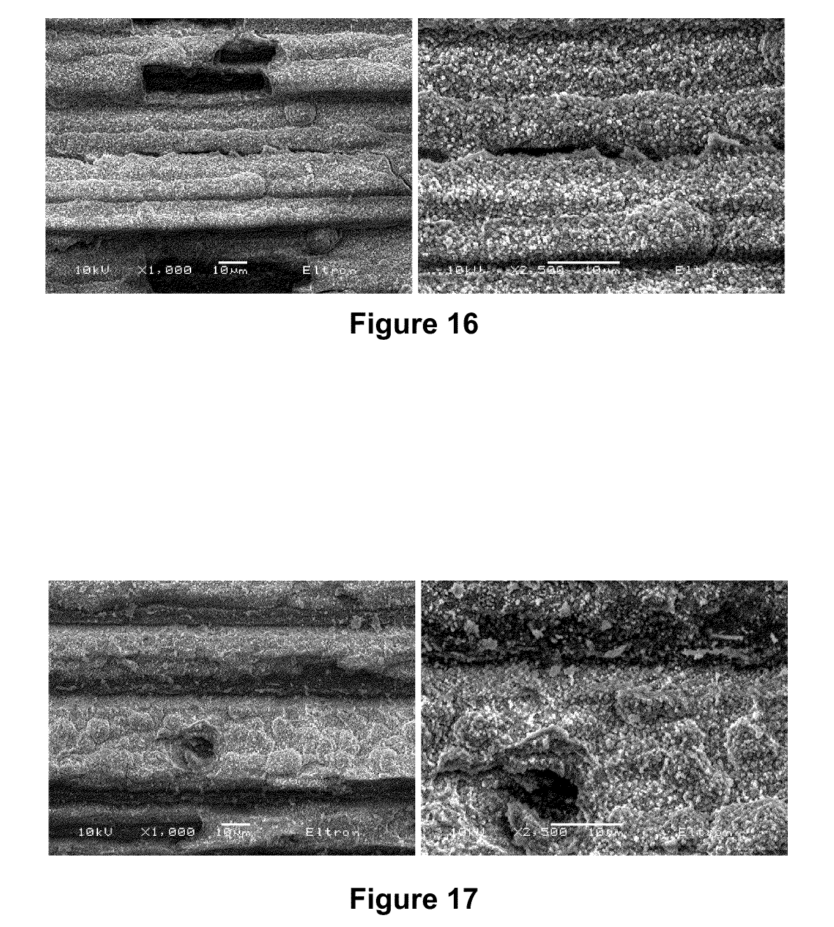

SEM is used to show that the morphology of AlN deposited at 700° C. FIGS. 16 and 17 show the surface of AlN deposited on Fe₃N and Fe₄N/Fe respectively. FIGS. 16 and 17 reveal a much more crystalline AlN coating than the AlN deposited at 650° C. Depending on deposition conditions, the uniform AlN coating may be crystalline, partly-crystalline or amorphous, as observed where the AlN coating deposited at 700° C. appears to be cracked in several places and several pores are present. In an aspect, crystalline or amorphous refers to characterization of the coating by X-ray diffraction, such that the AlN coating may be x-ray amorphous or x-ray crystalline, wherein the coating may contain relatively localized regions of crystalline or amorphous, although the bulk is characterized amorphous or crystalline, respectively. In an aspect, the deposited AlN film is crystalline or x-ray crystalline.

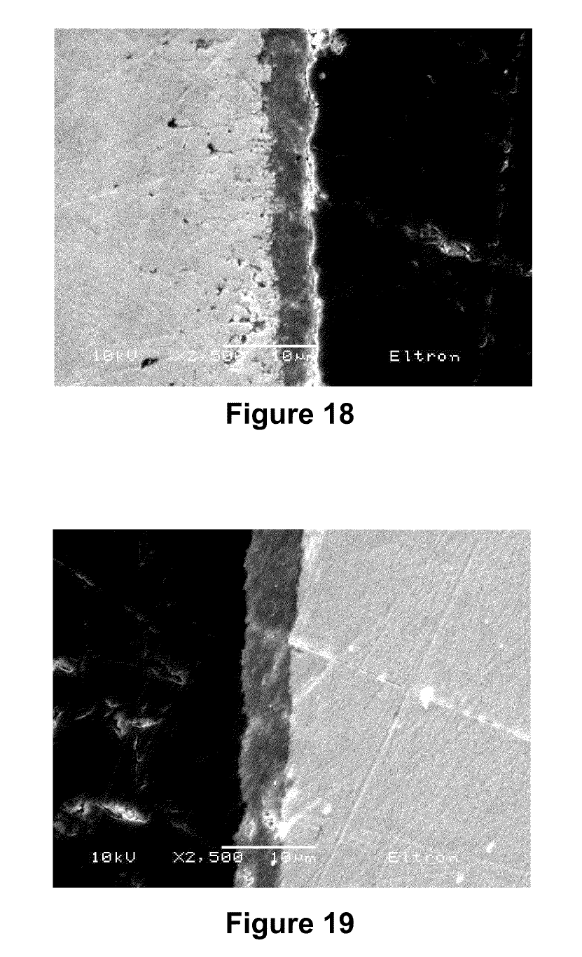

SEM cross section analysis is used to measure the thickness of the AlN deposited at 700° C. FIGS. 18 and 19 show a cross section SEM image of AlN deposited onto 1018 carbon steel with a Fe₃N and Fe₄N/Fe surface respectively.

The AlN coating in FIG. 18 is 4.5±0.6 μm thick and the AlN coating in FIG. 19 is 5.1±0.4 μm thick. It is also worth noting the appearance of the steel in each image. In FIG. 18 the surface of the steel appears porous. In FIG. 19 the surface of the steel appears dense. This is consistent with the surface SEM images of Fe₃N and Fe₄N/Fe shown previously in FIGS. 4 and 5. It is also worth noting that XRD confirmed that the surface that started as Fe₃N converted to Fe₄N/Fe and the cross section image in FIG. 18 shows that the morphology of Fe₃N is maintained even though the surface converted to Fe₄N/Fe.

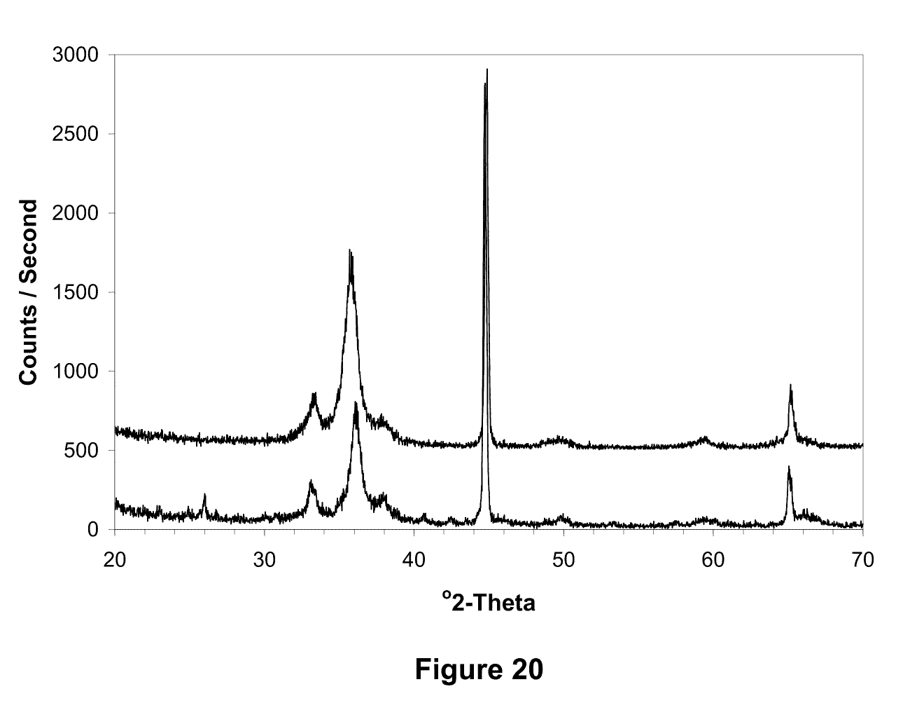

Characterization of Corrosion Resistance: After AlN is deposited and adhered to a steel surface, the coated sample can be exposed to an oxidizing agent such as air or oxygen to partially oxidize the surface of the AlN to Al₂O₃. This results in a corrosion resistant coating on the surface of steel that will prevent corrosion of the steel under harsh conditions such as steam pipes. A 1018 carbon steel sample with an aluminum nitride coating is exposed to air for four hours at 650° C. X-ray diffraction patterns before and after this partial oxidation step are shown in FIG. 20. This figure shows that before oxidation only AlN is found on the surface of the mild steel. Following the partial oxidation step both AlN and Al₂O₃ are found on the surface.

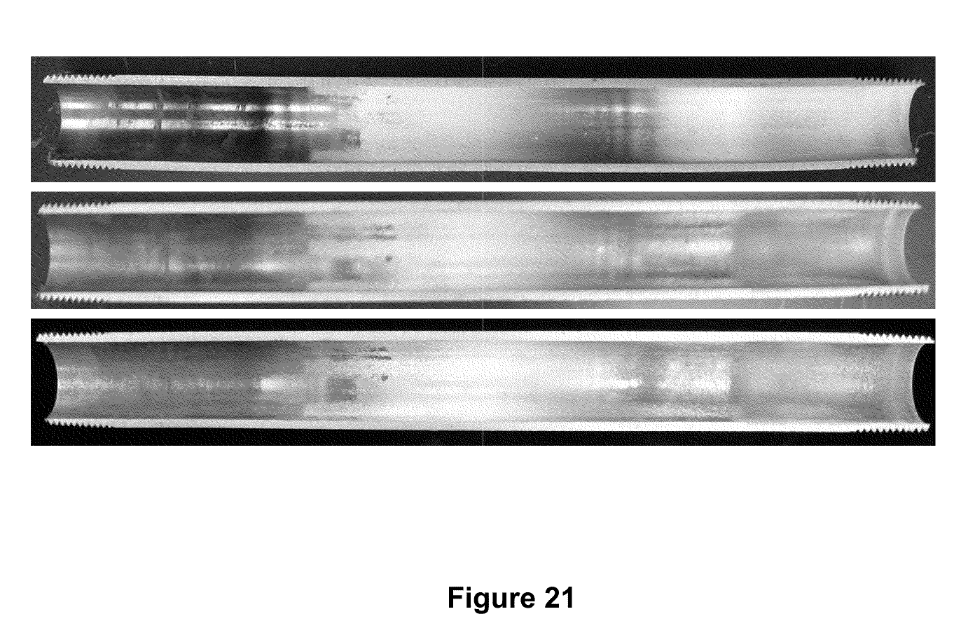

Corrosion in Air: An AlN coating is deposited on the interior surface of a 1″ diameter 1018 carbon steel pipe that is 12″ long. In this configuration only 1″ of the pipe is in the hot zone of the furnace and, therefore, a dense well-adhered AlN layer is only expected in the area of the pipe found in this hot zone. Following deposition, the coated pipe is cut in half lengthwise for further examination. The top image in FIG. 21 shows the interior surface of the pipe following deposition. The middle section of the pipe within the hot zone has a well-adhered AlN coating as expected. The sections of pipe to the left and right of the hot zone do not show deposited AlN coatings since these sections of pipe are not at the deposition temperature simply due to the furnace size. After six months exposed to air an image of the same length of pipe is obtained for comparison, as shown in the middle image in FIG. 21. Another image is obtained after 21 months (see bottom image in FIG. 21).

The three images in FIG. 21 show that after six months of air exposure the sections of pipe without an AlN coating have significantly corroded. After 21 months the corrosion is worse. The middle section of pipe with an AlN coating, however, does not corrode at all.

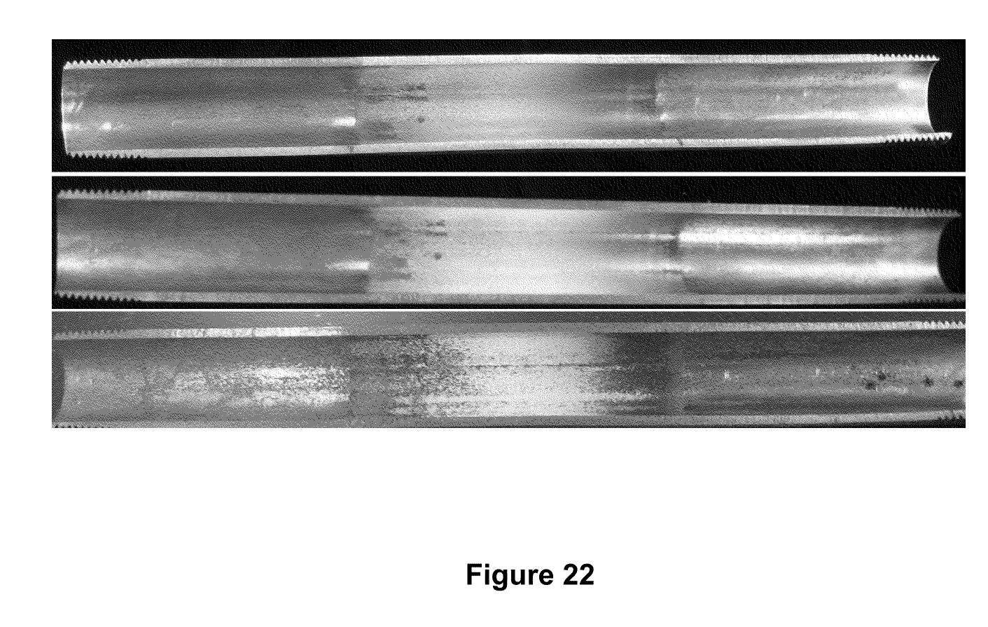

A steam corrosion experiment is performed on one half of the pipe. The coated half-pipe is enclosed in a quartz tube within two 12″ hot-zones. Air is bubbled through deionized water and into the first 12″ hot-zone to generate steam. The steam is then carried into the second 12″ hot-zone which contains the AlN coated samples. FIG. 22 shows the results of steam corrosion testing.

The top image in FIG. 22 shows the deposited AlN. The ends of the pipe are cleaned by mechanical abrasion prior to steam corrosion testing. The middle image shows the test pipe after 336 hours exposed to steam/air at 200° C. Some rusting/corrosion is visible on the left side of the pipe, but the area of pipe coated with AlN appears to be corrosion free. The bottom image in FIG. 22 shows the pipe after exposure to steam/air after 672 hours. The sample is significantly corroded. In the area coated with AlN some corrosion is present; however, the areas coated with completely dense AlN are not corroded. It should be noted that stagnant water was present which may have accelerated rusting corrosion. The images in FIG. 22 show that an AlN/Al₂O₃ coated steel by a process of the present invention functions well as a corrosion resistant coating in steam pipes.

Mechanical Testing: ASTM D3359-02 is used to characterize how well the AlN adheres or bonds to the 1018 steel substrate. In this test the AlN coating is scored, tape is applied to the surface, and the tape is slowly pulled away. The amount of AlN that delaminates with the tape is then documented.

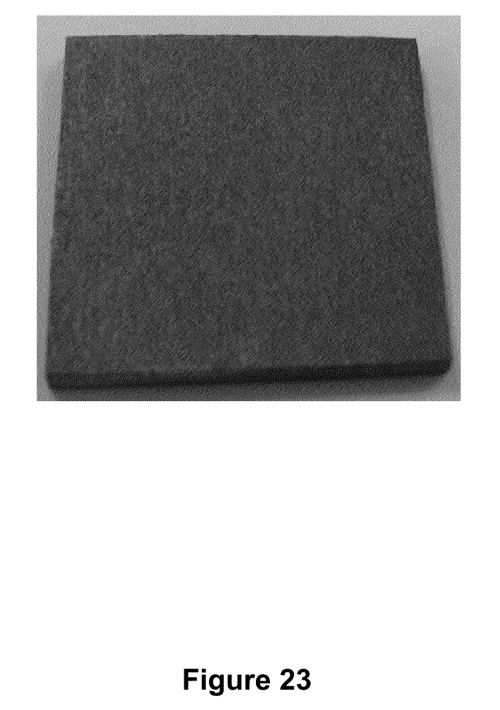

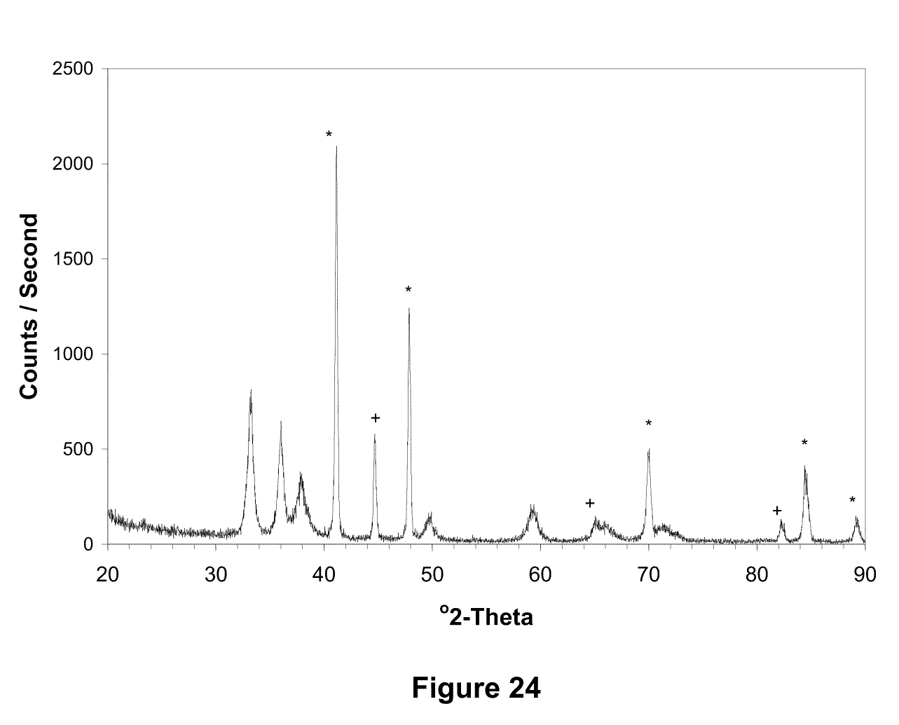

The tape test sample is prepared by depositing AlN onto a 1018 carbon steel coupon with a Fe₃N surface. The deposition is performed for 30 minutes at 700° C., 4.5 mL/min N₂ carrier gas, and 350-690 mTorr. FIG. 23 shows a digital image of the deposited AlN and FIG. 24 shows an X-ray diffraction pattern of the sample following deposition.

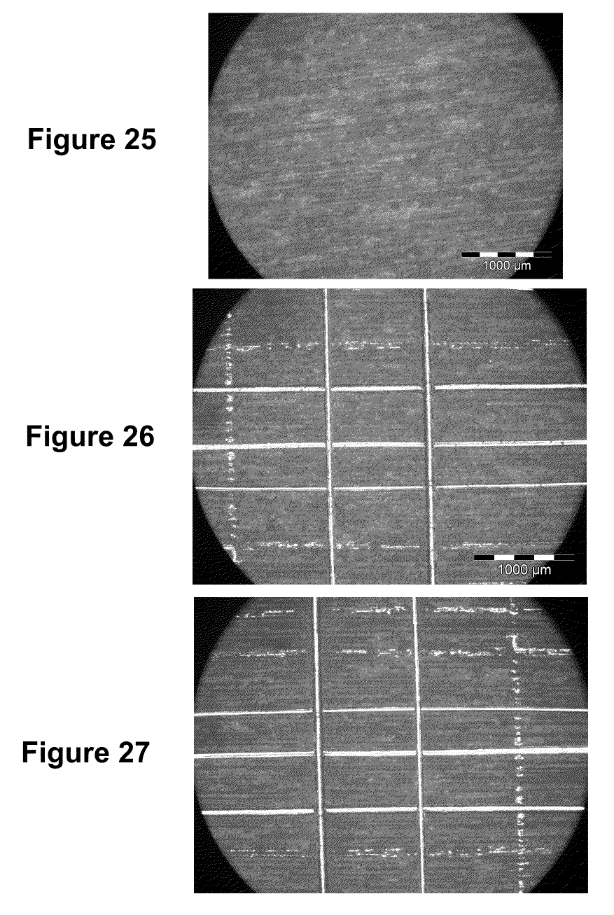

FIG. 25 shows an optical microscope image of the AlN surface deposited onto 1018 steel at 700° C. FIG. 26 shows the same surface after being scored. The scoring penetrates all the way through the AlN coating, but the coating does not flake off. Finally, FIG. 27 shows the surface after tape testing.

Comparing FIGS. 26 and 27 shows that little to no AlN is removed by the tape. Even at the intersection of the scoring, little AlN has delaminated from the steel. This indicates that the AlN deposited under the conditions described above is very well adhered to the steel.

Deposition of AlN onto AlN: AlN is deposited onto an AlN substrate using the same CVD reactor described previously. The reactor is purged of air and heated to the deposition temperature (650° C.) under a N₂ flow rate of 4.5 mL/minute and a 350 mTorr vacuum. Once at temperature the CVD precursor is heated to 220° C. which is sufficiently high to rapidly vaporize the precursor for high AlN deposition rates not achieved in conventional processes. As the precursor is vaporized, it is carried into the CVD reactor by one or both of the flow of a carrier gas (e.g., nitrogen gas) and vacuum. Deposition is allowed to occur for 30 minutes. The reactor is then allowed to cool under flowing nitrogen gas. The coated sample is mounted in epoxy and the cross section characterized with SEM to determine the thickness of the deposited AlN layer. The thickness is measured to be five μm.

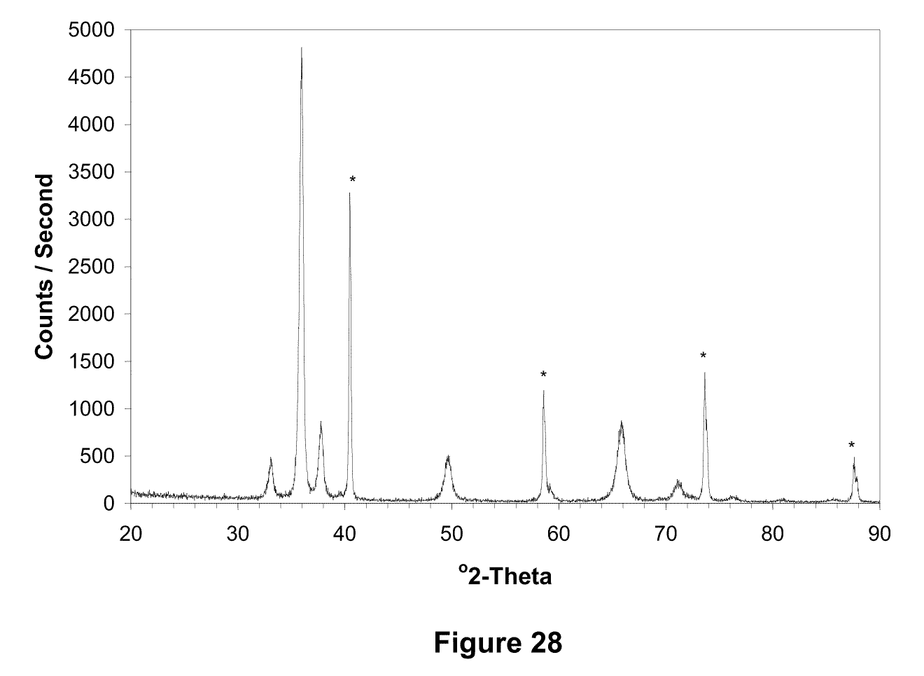

Deposition of AlN onto Mo: AlN is deposited onto a molybdenum foil substrate using a tube furnace to heat the sample rather than a cartridge heater. The reactor is purged of air and heated to the deposition temperature (800-900° C.) under a N₂ flow rate of 10 mL/minute and a 586 mTorr vacuum. Once at temperature the CVD precursor is heated to 220° C. which is sufficiently high to rapidly vaporize the precursor for high AlN deposition rates. As the precursor is vaporized it is carried into the CVD reactor by the flow of a carrier gas (e.g., nitrogen gas) and vacuum. During vaporization of the precursor the vacuum reaches 1037 mTorr. Deposition is allowed to occur for 30 minutes. The reactor is then allowed to cool under flowing nitrogen gas. The sample has a well adhered coating of AlN. The sample is characterized with X-ray diffraction as shown in FIG. 28.

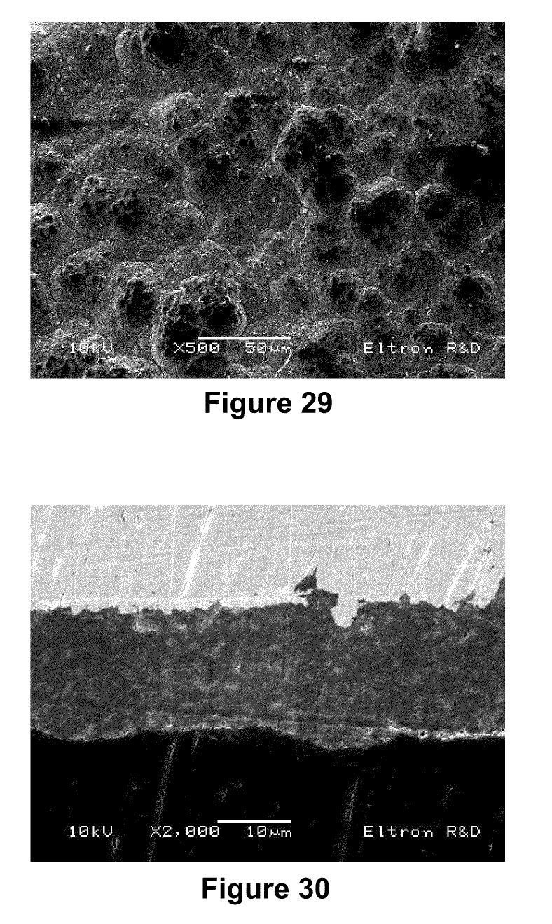

SEM is used to characterize the surface and measure the thickness of the deposited AlN, as shown in FIGS. 29 and 30 respectively. The deposited aluminum nitride is dense and has a thickness of 18±1 μm. This corresponds to a deposition rate of 0.6 μm/min.

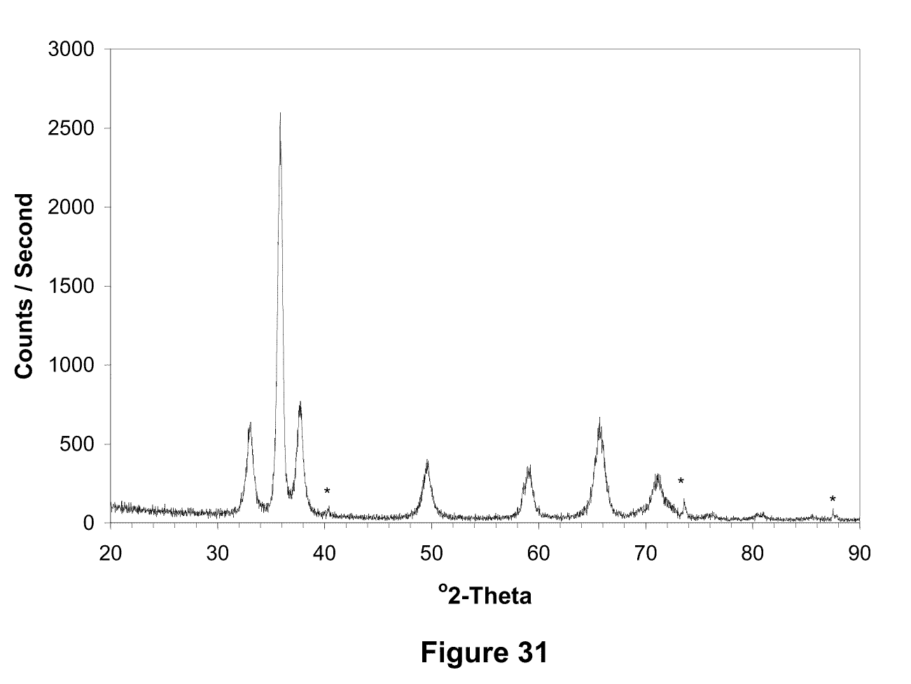

Thicker AlN coatings on molybdenum are prepared using the following conditions. The reactor is purged of air and heated to the deposition temperature (800-900° C.) under a N₂ flow rate of 20 mL/minute and an 1148 mTorr vacuum. Once at temperature the CVD precursor is heated to 220° C. which is sufficiently high to rapidly vaporize the precursor for high AlN deposition rates. As the precursor is vaporized it is carried into the CVD reactor by the nitrogen flow rate and vacuum. During vaporization of the precursor the vacuum reaches 1739 mTorr. Deposition is allowed to occur for 80 minutes. The reactor is then allowed to cool under flowing nitrogen. The sample has a well adhered coating of AlN. The sample is characterized with X-ray diffraction, as shown in FIG. 31.

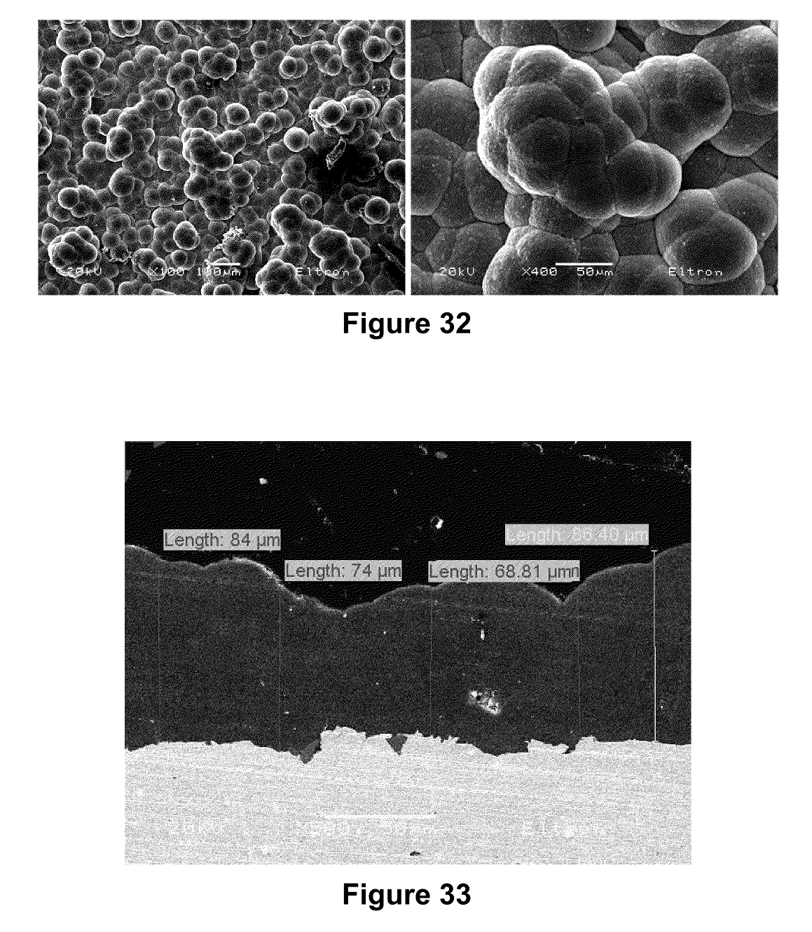

FIG. 31 shows that the AlN is thick enough that the Mo diffraction peaks are barely visible by XRD. SEM is used to characterize the surface and measure the thickness of the deposited AlN, as shown in FIGS. 32 and 33, respectively. The deposited aluminum nitride is dense and has a thickness of 74±14 micron. This corresponds to a deposition rate of 0.93 μm/min.

These examples demonstrate that composition of the iron nitride interface can be controlled before and during AlN deposition onto steel. In addition, the thickness of the deposited AlN layer onto any surface can be controlled by temperature, pressure, and deposition time. AlN deposited on steel by the method described above is well adhered and provides various beneficial functional attributes, including corrosion and/or wear resistant surfaces.

When a group of substituents is disclosed herein, it is understood that all individual members of that group and all subgroups, including any isomers, enantiomers, and diastereomers of the group members, are disclosed separately. When a Markush group or other grouping is used herein, all individual members of the group and all combinations and subcombinations possible of the group are intended to be individually included in the disclosure. A number of specific groups of variable definitions have been described herein. It is intended that all combinations and subcombinations of the specific groups of variable definitions are individually included in this disclosure. Compounds described herein may exist in one or more isomeric forms, e.g., structural or optical isomers. When a compound is described herein such that a particular isomer, enantiomer or diastereomer of the compound is not specified, for example, in a formula or in a chemical name, that description is intended to include each isomers and enantiomer (e.g., cis/trans isomers, R/S enantiomers) of the compound described individual or in any combination. Additionally, unless otherwise specified, all isotopic variants of compounds disclosed herein are intended to be encompassed by the disclosure. For example, it will be understood that any one or more hydrogens in a molecule disclosed can be replaced with deuterium or tritium. Isotopic variants of a molecule are generally useful as standards in assays for the molecule and in chemical and biological research related to the molecule or its use. Isotopic variants, including those carrying radioisotopes, may also be useful in diagnostic assays and in therapeutics. Methods for making such isotopic variants are known in the art. Specific names of compounds are intended to be exemplary, as it is known that one of ordinary skill in the art can name the same compounds differently.

Molecules disclosed herein may contain one or more ionizable groups [groups from which a proton can be removed (e.g., —COOH) or added (e.g., amines) or which can be quaternized (e.g., amines)]. All possible ionic forms of such molecules and salts thereof are intended to be included individually in the disclosure herein. With regard to salts of the compounds herein, one of ordinary skill in the art can select from among a wide variety of available counterions those that are appropriate for preparation of salts of this invention for a given application. In specific applications, the selection of a given anion or cation for preparation of a salt may result in increased or decreased solubility of that salt.

Every formulation or combination of components described or exemplified herein can be used to practice the invention, unless otherwise stated.

Whenever a range is given in the specification, for example, a temperature range, a time range, a pH range, a pressure range, or a composition or concentration range, all intermediate ranges and subranges, as well as all individual values included in the ranges given are intended to be included in the disclosure. The upper and lower limits of the range may themselves be included in the range. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when compositions of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. The broad term comprising is intended to encompass the narrower consisting essentially of and the even narrower consisting of. Thus, in any recitation herein of a phrase “comprising one or more claim element” (e.g., “comprising A and B), the phrase is intended to encompass the narrower, for example, “consisting essentially of A and B” and “consisting of A and B.” Thus, the broader word “comprising” is intended to provide specific support in each use herein for either “consisting essentially of” or “consisting of.” The invention illustratively described herein suitably may be practiced in the absence of any element or elements, limitation or limitations which is not specifically disclosed herein.

One of ordinary skill in the art will appreciate that starting materials, catalysts, reagents, synthetic methods, purification methods, analytical methods, and assay methods, other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by examples, preferred embodiments and optional features, modification and variation of the concepts herein disclosed may be resorted to by those skilled in the art, and that such modifications and variations are considered to be within the scope of this invention as defined by the appended claims.

TABLE 1
Gas Compositions Tested for Iron Nitride Formation.

| Nitriding Gas Composition | | | Iron Nitride Phase |
|---|---|---|---|
| NH₃ | H₂ | N₂ | Observed |
| 20-60% | 80-40% | 0% | Fe₄N |
| 20-60% | 0% | 80-40% | Fe₄N/Fe₃N |
| 100% | 0% | 0% | Fe₃N |

We claim:

1. A chemical vapor deposition process for high-rate deposition of a dense aluminum nitride coating onto a solid surface, the process comprising:
providing said solid surface;
heating and vaporizing an aluminum nitride precursor; and
exposing at least a portion of said solid surface to said heated and vaporized aluminum nitride precursor, thereby depositing aluminum nitride on said solid surface, wherein said aluminum nitride deposition rate is greater than or equal to 0.05 μm/min.

2. The process of claim 1 wherein the aluminum nitride precursor is an aluminum chloride ammonia complex with the formula AlCl₃(NH₃)ₓ, where x=1-6.

3. The process of claim 1, wherein said solid surface is heated and exposed to a partial vacuum.

4. The process of claim 1 wherein the solid surface is a metallic substrate.

5. The process of claim 1 wherein the metallic substrate comprises a material selected from the group consisting of: aluminum, molybdenum, manganese, and alloys thereof.

6. The process of claim 1 wherein the solid surface is silicon.

7. The process of claim 1 wherein the solid surface is a ceramic.

8. The process of claim 7 wherein the ceramic is aluminum nitride.

9. The process of claim 1, wherein the vaporized precursor is conveyed to said solid surface at least in part by an inert carrier gas.

10. The process of claim 9 wherein the inert carrier gas is argon or nitrogen.

11. The process of claim 9 wherein the inert carrier gas has a flow rate selected from a range that is greater than or equal to 1 mL/min and less than or equal to 100 mL/min.

12. The process of claim 1 wherein the solid surface is heated to a temperature that is greater than or equal to 250° C. and less than or equal to 1000° C.

13. The process of claim 1 wherein the solid surface is heated to a temperature that is greater than or equal to 550° C. and less than or equal to 850° C.

14. The process of claim 1, wherein the exposing step occurs at a deposition pressure, wherein the deposition pressure is selected from a range that is greater than or equal to 50 mTorr and less than or equal to 2000 mTorr.

15. The process of claim 1, wherein the aluminum nitride coating deposition rate is selected from a range that is greater than or equal to 0.05 μm/min and less than or equal to 10 μm/min.

16. The process of claim 1, wherein the aluminum nitride coating has a density, wherein said density is greater than or equal to 3 g/cm³.

17. A chemical vapor deposition process for depositing and adhering a dense aluminum nitride corrosion resistant layer onto a steel surface, the process comprising:
nitriding the steel surface to form an iron nitride;
heating and vaporizing at least one aluminum nitride precursor; and
exposing at least a portion of said nitrided steel surface to said at least one heated and vaporized aluminum nitride precursor;
thereby depositing and adhering aluminum nitride on said nitrided steel surface.

18. The process of claim 17, wherein the nitriding step comprises flowing a nitriding gas composition comprising ammonia over at least a portion of said steel surface to form an iron nitride layer over at least a portion of said steel surface.

19. The process of claim 18, wherein the steel surface is heated to a temperature that is selected from a range that is greater than or equal to 450° C. and less than or equal to 650° C. during the flow of the nitriding gas composition, thereby forming the iron nitride on the steel surface, wherein the iron nitride has the formula FeₓN, wherein 2≦x≦3.

20. The process of claim 18, wherein the nitriding gas composition further comprises hydrogen gas and the ratio of ammonia (NH₃) to hydrogen (H₂) is selected from a range that is greater than or equal to 3.5:1 and less than or equal to 4.5:1, and the steel surface is heated to a temperature that is selected from a range that is greater than or equal to 450° C. and less than or equal to 650° C. during the flow of the nitriding gas composition to form an iron nitride and iron surface on the steel, wherein said iron nitride is Fe₄N.

21. The process of claim 18, wherein the composition of the iron nitride on the surface of the steel substrate is FeₓN wherein 1≦x≦5.

22. The process of claim 18, wherein the iron nitride has the formula FeₓN, wherein the value of x changes during the deposition process.

23. The process of claim 17, wherein said steel surface is heated under a partial vacuum.

24. The process of claim 17 wherein the aluminum nitride precursor used in the chemical vapor deposition process is an aluminum chloride ammonia complex having the formula AlCl₃(NH₃)ₓ, wherein x=1-6.

25. The process of claim 17 further comprising: reacting the deposited aluminum nitride with air to form an aluminum oxide surface on a surface of the aluminum nitride layer exposed to said air.

26. The process of claim 17 further comprising: reacting the deposited aluminum nitride with oxygen to form an aluminum oxide surface on a surface of the aluminum nitride layer exposed to said oxygen.

27. The process of claim 17 wherein the solid surface is heated to a temperature that is selected from a range that is greater than or equal to 550° C. and less than or equal to 850° C.

28. The process of claim 17 wherein the deposition occurs at a pressure that is selected from a range that is greater than or equal to 50 mTorr and less than or equal to 2000 mTorr.

29. The process of claim 17, wherein said vaporized precursor is carried to said steel surface at least in part by an inert carrier gas.

30. The process of claim 29 wherein the carrier gas has a flow rate selected from a range that is greater than or equal to 1 mL/min and less than or equal to 100 mL/min.

31. The process of claim 17, wherein the nitriding step comprises exposing the steel surface with a nitriding gas composition.

32. The process of claim 31, wherein the nitriding gas composition comprises NH₃.

33. The process of claim 32, wherein said nitriding gas composition further comprises at least one of:
H₂ gas;
N₂ gas; or
a mixture of H₂ gas and N₂ gas;
wherein said nitriding gas composition comprises greater than or equal to 20% and less than or equal to 60% NH₃.

34. The process of claim 32, wherein said nitriding gas composition comprises greater than 95% NH₃.

35. The process of claim 17, wherein the aluminum nitride corrosion resistant layer has a density, wherein said density is greater than or equal to 3 g/cm³.
